(19) United States
(12) Patent Application Publication
(10) Pub. No.: US 2026/0101733 A1
(43) Pub. Date: Apr. 9, 2026

(54) SEMICONDUCTOR ELEMENT AND MANUFACTURING METHOD THEREOF

(71) Applicant: National Cheng Kung University, Tainan City (TW)

(72) Inventors: Wei-Chen TU, Tainan City (TW); Yi-Hsiang SHIH, Tainan City (TW)

(73) Assignee: National Cheng Kung University, Tainan City (TW)

(21) Appl. No.: 19/225,805

(22) Filed: Jun. 2, 2025

(30) Foreign Application Priority Data
Oct. 8, 2024 (TW) 113138340

(51) Int. Cl. H01L 21/768; H01L 23/532

(52) U.S. Cl. CPC H10W 20/064; H10W 20/4462

(57) ABSTRACT

A method for manufacturing a semiconductor element includes a preparation step, a protective gas introduction step, a reaction gas introduction step, and a deposition step. Firstly, a semiconductor sample is prepared on a stage of a cavity, where a line width of a circuit pattern layer of the semiconductor sample is less than 100 nm. Then, the stage is heated to and maintained at 250° C. to 480° C., and plasma is activated in a protective atmosphere to crack introduced benzene vapor to form a graphene layer on the circuit pattern layer, where a thickness of the graphene layer is 0.3 nm to 4.5 nm. The reaction can be carried out at a low temperature using the benzene vapor as a carbon source, improving properties of graphene deposited on a surface of the circuit pattern layer, and greatly reducing resistance of the circuit pattern layer.

### CROSS-REFERENCE TO RELATED APPLICATION

This non-provisional application claims priority under 35 U.S.C. § 119 (a) to patent application No. 113138340 filed in Taiwan, R.O.C. on Oct. 8, 2024, the entire contents of which are hereby incorporated by reference.

### BACKGROUND

### Technical Field

The present invention relates to the field of semiconductors, and in particular, to a semiconductor element and a manufacturing method thereof.

### Related Art

As a line width of a semiconductor element is gradually reduced, resistance of a copper wire significantly increases, leading to a thermal loss of a current and heat accumulation in the element, consequently reducing a service life. With the recent rise of artificial intelligence, the impact of resistance has been emphasized.

Currently, an improvement method is trying to plate a circuit pattern layer with a material with higher electrical conductivity, for example, a copper plate is coated with graphene. However, existing methods for preparing graphene all have disadvantages. For example, vacuum plating using methane as a carbon source requires the temperature of a cavity to reach nearly 1000° C., which is likely to cause thermal damage to a substrate material. In addition, it is common to plate the whole surface of metal foil, making subsequent processing complex, so that this method can be hardly applied to a circuit pattern with a smaller line width. In another example, a graphene layer is prepared by using a solution method. In this way, the uniformity and thickness of graphene can be hardly controlled.

### SUMMARY

To resolve the foregoing problem, a method for manufacturing a semiconductor element is provided. In some embodiments, the method for manufacturing the semiconductor element includes a preparation step, a protective gas introduction step, a reaction gas introduction step, and a deposition step. In the preparation step, a semiconductor sample is prepared and placed on a stage of a cavity, the semiconductor sample includes a semiconductor substrate and a circuit pattern layer, the circuit pattern layer is on the semiconductor substrate, and a line width of the circuit pattern layer is less than 100 nm.

In the protective gas introduction step, the cavity is vacuumized, a protective gas is introduced, and the stage is heated to 250° C. to 480° C. In the reaction gas introduction step, introduction of the protective gas is stopped, a reaction gas is introduced, and a temperature of the stage is maintained at 250° C. to 480° C., where the reaction gas includes a hydrogen gas and benzene vapor.

In the deposition step, the protective gas is reintroduced, plasma is activated, and the temperature of the stage is maintained at 250° C. to 480° C., so that the benzene vapor cracks to form a graphene layer on the circuit pattern layer, where a thickness of the graphene layer is 0.3 nm to 4.5 nm.

In some embodiments, a material of the circuit pattern layer is selected from the group consisting of copper, nickel, aluminum, and an alloy thereof.

In some embodiments, the line width of the circuit pattern layer is less than 60 nm. In some embodiments, the thickness of the graphene layer is 0.3 nm to 3 nm.

In some embodiments, in the protective gas introduction step, the reaction gas introduction step, and the deposition step, the temperature of the stage is maintained at 300° C. to 400° C.

In some embodiments, in the deposition step, a flow rate of the introduced protective gas is 10 to 75 standard cubic centimeters per minute (sccm), and a flow rate of the introduced reaction gas is less than 15 sccm.

A semiconductor element is further provided. In some embodiments, the semiconductor element includes a semiconductor substrate, a circuit pattern layer, and a graphene layer. The circuit pattern layer is on the semiconductor substrate, and a line width of the circuit pattern layer is less than 100 nm. The graphene layer is on a surface of the circuit pattern layer, and a thickness of the graphene layer is 0.3 nm to 4.5 nm.

In some embodiments, a material of the circuit pattern layer is selected from the group consisting of copper, nickel, aluminum, and an alloy thereof.

In some embodiments, the line width of the circuit pattern layer is less than 60 nm. In some embodiments, the thickness of the graphene layer is 0.3 nm to 3 nm.

As described in the foregoing embodiments, based on the characteristic that graphene is formed only on a metal surface, benzene vapor as a carbon source is cracked and deposited by plasma at a low temperature to form a single layer or multiple layers of graphene on a surface of the circuit pattern layer, greatly reducing resistance of the circuit.

### BRIEF DESCRIPTION OF THE DRAWINGS

FIG. 1 is a flowchart of a method for manufacturing a semiconductor element.

FIG. 2 is a schematic diagram of a device for manufacturing a semiconductor element.

FIG. 3 is a top view of a part of a semiconductor sample.

FIG. 4 is a cross-sectional diagram of a part of a semiconductor sample.

FIG. 5 is a scanning electron micrograph according to an embodiment of a semiconductor element.

FIG. 6 is a scanning electron micrograph according to another embodiment of a semiconductor element.

### DETAILED DESCRIPTION

In the following description, the terms “first”, “second”, and “third” are used only to distinguish an element, component, region, layer, or portion from another element, component, region, layer, or portion, but not intended to indicate a necessary sequence thereof. In addition, relative terms such as “lower” and “upper” as well as “inside” and “outside” may be used herein to describe a relationship between an element and another element. It should be understood that the relative terms are intended to include different orientations of a device other than those shown in the figures. For example, if a device in a figure is inverted, an element described as being on a “lower” side of another element is oriented on an “upper” side of the another element. This only indicates a relative orientation relationship, but not an absolute orientation relationship.

In the accompanying drawings, widths of some elements, regions, and the like are enlarged for clarity. Throughout this specification, identical reference numerals in the accompanying drawings indicate same elements. It should be understood that, for example, when an element is described as being “on” or “connected to” another element, the element may be directly on or connected to the another element, or an intermediate element may be present. In another case, when an element is described as being “directly on another element” or “directly connected to” another element, an intermediate element is not present.

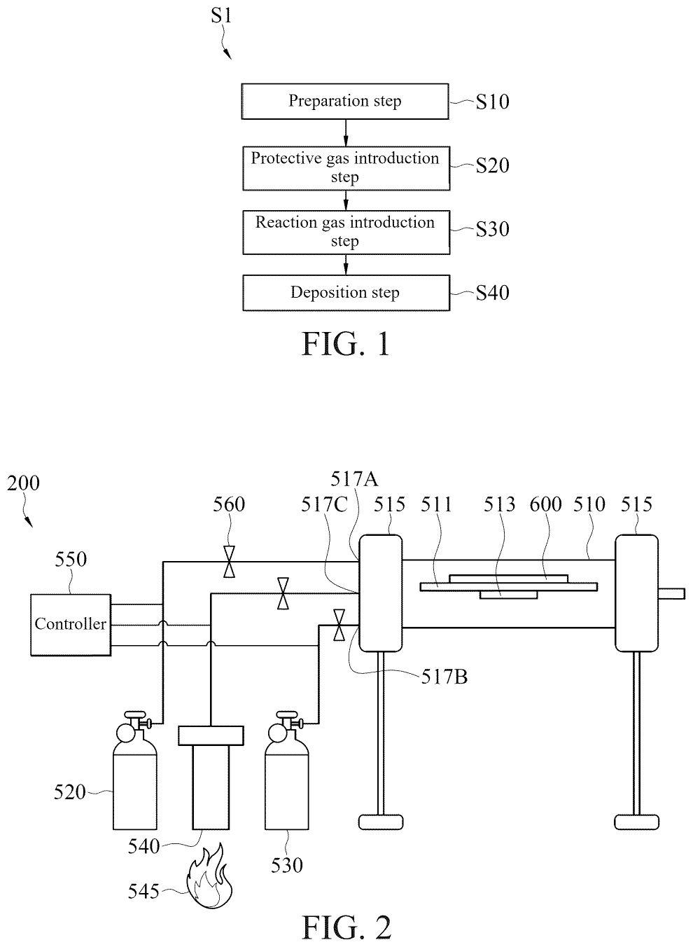

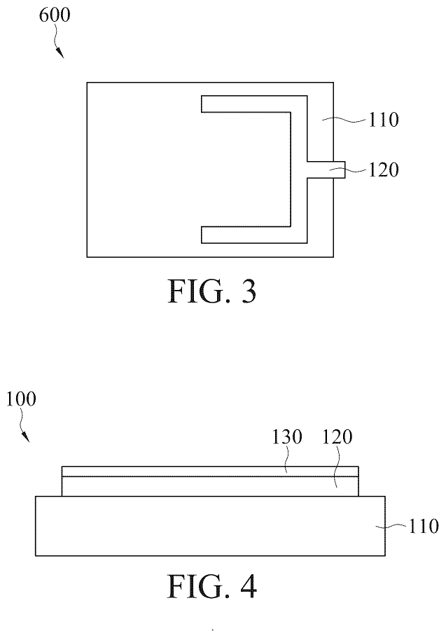

FIG. 1 is a flowchart of a method for manufacturing a semiconductor element. FIG. 2 is a schematic diagram of a device for manufacturing a semiconductor element. FIG. 3 is a top view of a part of a semiconductor sample. As shown in FIG. 1 to FIG. 3, a method S1 for manufacturing a semiconductor element includes a preparation step S10, a protective gas introduction step S20, a reaction gas introduction step S30, and a deposition step S40.

As shown in FIG. 2, a device 200 for manufacturing a semiconductor element includes a cavity 510, a protective gas tank 520, a hydrogen tank 530, a benzene tank 540, and a controller 550. The cavity 510 includes a stage 511, a heating device 513, and a vacuum device 515. The benzene tank 540 is further provided with a heater 545 that can heat liquid benzene into benzene vapor. A first introduction end 517A, a second introduction end 517B, and a third introduction end 517C of the cavity 510 are respectively connected to the protective gas tank 520, the hydrogen tank 530, and the benzene tank 540, and control valves 560 are used to control gas introduction amounts.

Refer to FIG. 1 to FIG. 3 together. In the preparation step S10, a semiconductor sample 600 is prepared and placed on the stage 511 of the cavity 510, the semiconductor sample 600 includes a semiconductor substrate 110 and a circuit pattern layer 120, the circuit pattern layer 120 is on the semiconductor substrate 110, and a line width of the circuit pattern layer 120 is less than 100 nm. The semiconductor sample 600 is a semi-finished product of a semiconductor element 100.

In the protective gas introduction step S20, the cavity 510 is vacuumized by the vacuum device 515, and then the controller 550 controls the protective gas tank 520 to introduce a protective gas. The protective gas may be an argon gas or a helium gas. In addition, the controller 550 controls the heating device 513 to heat the stage 511 to 250° C. to 480° C., preferably 300° C. to 400° C., for example, 350° C. to 380° C.

In the reaction gas introduction step S30, introduction of the protective gas is stopped, the hydrogen tank 530 and the benzene tank 540 are controlled to introduce a hydrogen gas and benzene vapor as a reaction gas, and a temperature of the stage 511 is maintained at 250° C. to 480° C.

In the deposition step S40, the protective gas is reintroduced, and plasma is activated, where frequency and energy of the plasma are respectively 10 MHz to 20 MHz and 250 W to 400 W. The temperature of the stage 511 is maintained at 250° C. to 480° C. The benzene vapor cracks under the action of the plasma and the heat source to form a graphene layer 130 (as shown in FIG. 4) on the circuit pattern layer 120, where a thickness of the graphene layer 130 is 0.3 nm to 4.5 nm. Then, after cooling down and discharge of the reaction gas and the protective gas, the completed semiconductor element 100 may be taken out. In addition, in the deposition step S40, a flow rate of the introduced protective gas is 10 sccm to 75 sccm, and a flow rate of the introduced reaction gas is less than 15 sccm, in a ratio of about 5:1.

FIG. 4 is a cross-sectional diagram of a part of a semiconductor sample. As shown in FIG. 4, the semiconductor element 100 is obtained according to the foregoing manufacturing method, and includes a semiconductor substrate 110, a circuit pattern layer 120, and a graphene layer 130. The circuit pattern layer 120 is on the semiconductor substrate 110, and a line width of the circuit pattern layer 120 is less than 100 nm. The graphene layer 130 is on a surface of the circuit pattern layer 120, and a thickness of the graphene layer 130 is 0.3 nm to 4.5 nm. The graphene layer 130 may be controlled to be a single layer or multiple layers with a thickness of about 0.3 nm to 3 nm.

More specifically, a material of the circuit pattern layer 120 is selected from the group consisting of copper, nickel, aluminum, and an alloy thereof. preferably copper or a copper-nickel alloy. In addition, in some embodiments, the line width of the circuit pattern layer 120 is less than 60 nm, for example, 45 nm. However, this is only an example but is not for limiting. In fact, this has only been made and verified successfully for laboratory equipment. It should be possible to make the line width even smaller for higher-order equipment.

The following description is made based on an actual experiment. The mainly used manufacturing device 200 is MKS T11-301 including a tubular high-temperature furnace as the cavity 510 equipped with a gas flow meter, with a ULVAC GLD-N280 vacuum pump and a TTR91 Pfeiffer GmbH vacuum measurement system as the vacuum device 515, AK3540S 2P 4T 4T as the control valve 560, a pressure meter, a WEINTEK MT8102iE PLC human-machine interface controller as the controller 550, and a Seren USA SU-R301 radio-frequency plasma source.

After manufacturing, whether the deposited material is graphene is determined by using Horiba Jobin Yvon's Labram HR as a micro-Raman measurement machine, with a common SEM for structure inspection.

First, the semiconductor sample 600 with the circuit pattern layer 120 in a film state on the semiconductor substrate 110 is placed on the stage 511 of the cavity 510. The semiconductor substrate 110 is a silicon substrate with a silicon dioxide layer deposited on the surface. A minimum line width of the circuit pattern layer 120 is 45 nm. Then, process parameters are set on the PLC human-machine interface controller. The cavity is first vacuumized to 0.9 torr to 10 torr. At the same time, the heater 545 is started to heat the benzene tank 540, so that liquid benzene is transformed into benzene vapor. A heating temperature is about 78° C. to 80° C.

After the required vacuum environment is obtained, the protective gas introduction step S20 is carried out. An argon gas is introduced as a protective gas at a flow rate of 200 sccm for 1800 s. At the same time, the stage 511 is heated to 350° C. to 480° C. Next, in the reaction gas introduction step S30, introduction of the protective gas is stopped, and a hydrogen gas and benzene vapor are introduced as a reaction gas at a flow rate of 150 sccm for 3600 s.

Then, the argon gas is reintroduced, the flow rate of the hydrogen gas is reduced, and a voltage is applied to activate plasma for about 10 s to 30 s. The benzene vapor cracks due to energy of the plasma and thermal energy of the stage and the semiconductor sample 600, and is deposited only on the surface of the circuit pattern layer 120 based on the characteristic of graphene. In the deposition step S40, the flow rate of the argon gas is 10 sccm to 75 sccm, and the flow rate of the hydrogen gas is 0 sccm to 15 sccm.

Finally, introduction of the reaction gas is stopped, the protective gas is maintained, the stage 511 is cooled down to room temperature for about 1160 s, the residual gas is discharged, and the vacuum is broken, to complete manufacturing of the semiconductor element 100. Whether a peak value of the material with which the surface of the circuit pattern layer 120 is plated corresponds to that of graphene is determined by Raman spectroscopy. Duration for the deposition step S40 may be controlled to control the thickness of the graphene layer 130.

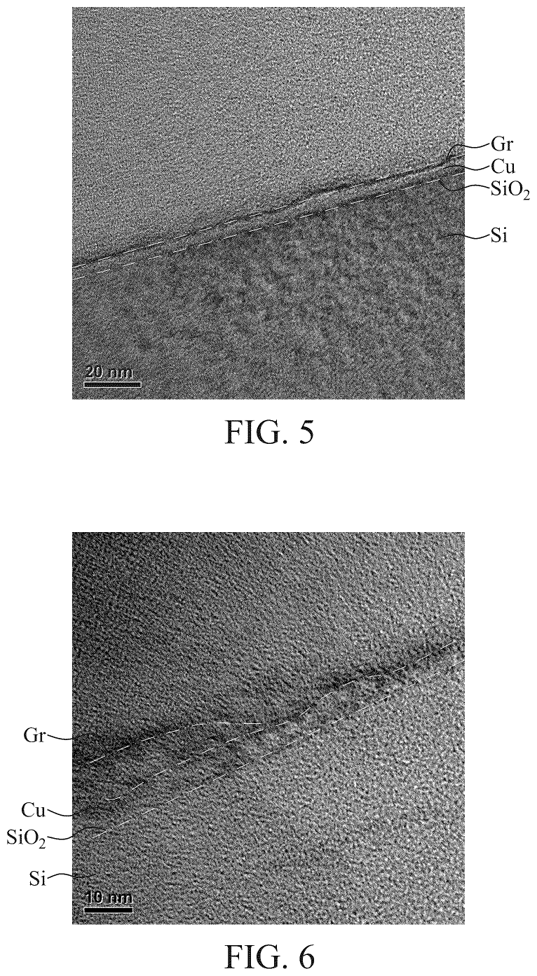

FIG. 5 is a scanning electron micrograph according to an embodiment of a semiconductor element. FIG. 6 is a scanning electron micrograph according to another embodiment of a semiconductor element. FIG. 5 shows a single layer of graphene (Gr) formed on the 45 nm circuit pattern layer 120 after 10 s of activation of plasma, with a thickness of about 0.3 nm. FIG. 6 shows multiple layers of graphene formed when the duration of the deposition step S40 is increased to 30 s, with a thickness of about 2 nm to 3 nm. It should be noted that an upper portion of the graphene is only a protective layer for making a scanning electron microscope specimen, but is not a part of the semiconductor element 100.

In conclusion, based on the characteristic that graphene is formed only on a metal surface, the benzene vapor as a carbon source is cracked and deposited by plasma at a low temperature to form a single layer or multiple layers of graphene on the surface of the circuit pattern layer 120, which can greatly reduce resistance of the circuit, and can provide a lower impedance loss for high-speed operation and high-frequency elements.

What is claimed is:

1. A method for manufacturing a semiconductor element, comprising:
a preparation step: preparing a semiconductor sample and placing the semiconductor sample on a stage of a cavity, wherein the semiconductor sample comprises a semiconductor substrate and a circuit pattern layer, the circuit pattern layer is on the semiconductor substrate, and a line width of the circuit pattern layer is less than 100 nm;
a protective gas introduction step: vacuumizing the cavity, introducing a protective gas, and heating the stage to 250° C. to 480° C.;
a reaction gas introduction step: stopping introducing the protective gas, introducing a reaction gas, and maintaining a temperature of the stage at 250° C. to 480° C., wherein the reaction gas comprises a hydrogen gas and benzene vapor; and
a deposition step: reintroducing the protective gas, activating plasma, and maintaining the temperature of the stage at 250° C. to 480° C., so that the benzene vapor cracks to form a graphene layer on the circuit pattern layer, wherein a thickness of the graphene layer is 0.3 nm to 4.5 nm.

2. The method for manufacturing the semiconductor element according to claim 1, wherein a material of the circuit pattern layer is selected from the group consisting of copper, nickel, aluminum, and an alloy thereof.

3. The method for manufacturing the semiconductor element according to claim 1, wherein the line width of the circuit pattern layer is less than 60 nm.

4. The method for manufacturing the semiconductor element according to claim 1, wherein the thickness of the graphene layer is 0.3 nm to 3 nm.

5. The method for manufacturing the semiconductor element according to claim 1, wherein in the protective gas introduction step, the reaction gas introduction step, and the deposition step, the temperature of the stage is maintained at 300° C. to 400° C.

6. The method for manufacturing the semiconductor element according to claim 1, wherein in the deposition step, a flow rate of the introduced protective gas is 10 sccm to 75 sccm, and a flow rate of the introduced reaction gas is less than 15 sccm.

7. A semiconductor element, comprising:
a semiconductor substrate;
a circuit pattern layer on the semiconductor substrate, wherein a line width of the circuit pattern layer is less than 100 nm; and
a graphene layer on a surface of the circuit pattern layer, wherein a thickness of the graphene layer is 0.3 nm to 4.5 nm.

8. The semiconductor element according to claim 7, wherein a material of the circuit pattern layer is selected from the group consisting of copper, nickel, aluminum, and an alloy thereof.

9. The semiconductor element according to claim 7, wherein the line width of the circuit pattern layer is less than 60 nm.

10. The semiconductor element according to claim 7, wherein the thickness of the graphene layer is 0.3 nm to 3 nm.
